(19) United States
(12) Patent Application Publication
(10) Pub. No.: US 2018/0308902 A1
(43) Pub. Date: Oct. 25, 2018

(54) OLED TOUCH DISPLAY DEVICE

(71) Applicant: SuperC-Touch Corporation, New Taipei City (TW)

(72) Inventors: Hsiang-Yu LEE, New Taipei City (TW); Shang CHIN, New Taipei City (TW); Ping-Tsun LIN, New Taipei City (TW); Chia-Hsun TU, New Taipei City (TW)

(21) Appl. No.: 15/491,412

(22) Filed: Apr. 19, 2017

(51) Int. Cl. H01L 27/32; G06F 3/041; G06F 3/044

(52) U.S. Cl. CPC H01L 27/323; G06F 3/0412; G06F 3/0416; G06F 2203/04104; H01L 27/3262; H01L 27/3276; G06F 2203/04112; G06F 3/044

(57) ABSTRACT

An OLED touch display device includes a TFT substrate and a touch electrode layer. The TFT substrate has a surface formed thereon plural switch devices, plural second touch traces and plural conductive pads. Each switch device has plural touch TFT switches. The touch electrode layer includes plural first touch traces and plural touch sense electrodes divided into plural groups each having at least one touch sense electrode, and each group is corresponding to one of the conductive pads. The touch sense electrodes are corresponding to the first touch traces one by on. Each touch sense electrode is connected to the corresponding first touch trace. Each first touch trace is connected to one touch TFT switch of the corresponding switch device, and each switch device is connected to one second touch trace and the corresponding conductive pad.

### BACKGROUND OF THE INVENTION

### 1. Field of the Invention

The present invention relates to a touch display panel and, more particularly, to an organic light emitting diode display (OLED) touch display device.

### 2. Description of Related Art

In recent years, the flat panel display industry has been rapidly developed, and many products have also been made in pursuit of light weight, thinness, small volume and fine image quality for developing several types of flat panel displays to replace traditional cathode ray tube display (CRT). The flat panel display includes liquid crystal display (LCD), plasma display panel (PDP), organic light emitting diode (OLED) display, field emission display (FED), and vacuum fluorescence display (VFD).

Among these types of flat panel displays, the organic light emitting diode display (OLED) technology is the one with great potential. The OLED display is provided with not only the advantages of LCD display including thinness, power-saving and full-color display, but also the features of wide viewing angle, self-illumination and fast response that are better than LCD.

Modern consumer electronic apparatuses are typically equipped with touch panels for use as their input devices. With the widespread use of smartphones, the multi-touch technique is getting more and more important. Generally, the multi-touch is implemented by projected capacitive touch technique.

When the touch sense resolution is increasing, the number of the touch sense electrodes and the number of the corresponding traces connected to the touch sense electrodes are also dramatically increasing. Typically, the touch sense electrodes are connected to a touch control circuit through the traces. With the large number of traces, it is difficult to route the number of traces between the touch sense electrodes and the touch control circuit. Moreover, the layout of the traces may occupy a lot of area, resulting in reducing the display area and lowering the display quality.

Therefore, it is desirable to provide an improved touch device to mitigate and/or obviate the afore-mentioned problems.

### SUMMARY OF THE INVENTION

The object of the present invention is to provide an OLED touch display device capable of greatly reducing the number of traces, significantly saving layout area and reducing the manufacturing cost in comparison with the prior art.

To achieve the object, there is provided an OLED touch display device, which comprises: a thin film transistor (TFT) substrate, a common voltage electrode layer, an OLED layer, an encapsulation layer, and at least one touch electrode layer. The TFT substrate has a surface formed thereon a plurality of switch devices, a plurality of second touch traces, a plurality of conductive pads, a plurality of display TFTs, a plurality of display pixel electrodes, a plurality of gate lines, and a plurality of data lines. Each switch device comprises a plurality of touch TFT switches. The common voltage electrode layer includes at least one common voltage electrode. The OLED layer is disposed between the TFT substrate and the common voltage electrode layer. The encapsulation layer is disposed at one side of the common voltage electrode layer opposite to the OLED layer. The at least one touch electrode layer is disposed at one side of the common voltage electrode layer opposite to the OLED layer, and includes a plurality of first touch traces and a plurality of touch sense electrodes divided into a plurality of groups each having at least one touch sense electrode, and each group is corresponding to one of the conductive pads. The plurality of touch sense electrodes are corresponding to the plurality of first touch traces one by one and each of the touch sense electrodes is connected to the corresponding first touch trace, while any tow touch sense electrodes are not connected with each other. Each of the first touch traces is connected to one touch TFT switch of one switch device corresponding thereto, and each of the switch devices is connected to one second touch trace and one conductive pad corresponding thereto.

### BRIEF DESCRIPTION OF THE DRAWINGS

FIG. 1 is a first exemplary stack-up diagram of the OLED touch display device in accordance with the present disclosure;

FIG. 2 is a schematic diagram of the OLED touch display device in accordance with the present disclosure;

FIG. 3 is a second exemplary stack-up diagram of the OLED touch display device in accordance with the present disclosure;

FIG. 4 is a third exemplary stack-up diagram of the OLED touch display device in accordance with the present disclosure;

FIG. 5 is a fourth exemplary stack-up diagram of the OLED touch display device in accordance with the present disclosure;

FIG. 6 is a fifth exemplary stack-up diagram of the OLED touch display device in accordance with the present disclosure;

FIG. 7 is a sixth exemplary stack-up diagram of the OLED touch display device in accordance with the present disclosure;

FIG. 8 is a seventh exemplary stack-up diagram of the OLED touch display device in accordance with the present disclosure;

FIG. 9 is another schematic diagram of the OLED touch display device in accordance with the present disclosure;

FIG. 10 is still another schematic diagram of the OLED touch display device in accordance with the present disclosure;

FIG. 11 is an eighth exemplary stack-up diagram of the OLED touch display device in accordance with the present disclosure;

FIG. 12 is a schematic view of the black matrix layer and the metal mesh touch sense electrode layer in accordance with the present disclosure;

FIG. 13 is a ninth exemplary stack-up diagram of the OLED touch display device in accordance with the present disclosure;

FIG. 14 is a tenth exemplary stack-up diagram of the OLED touch display device in accordance with the present disclosure;

FIG. 15 is an eleventh exemplary stack-up diagram of the OLED touch display device in accordance with the present disclosure; and

FIG. 16 is a schematic diagram illustrating the OLED touch display device with the touch sense electrodes being powered by a dedicated touch power source in accordance with the present disclosure.

### DETAILED DESCRIPTION OF THE PREFERRED EMBODIMENT

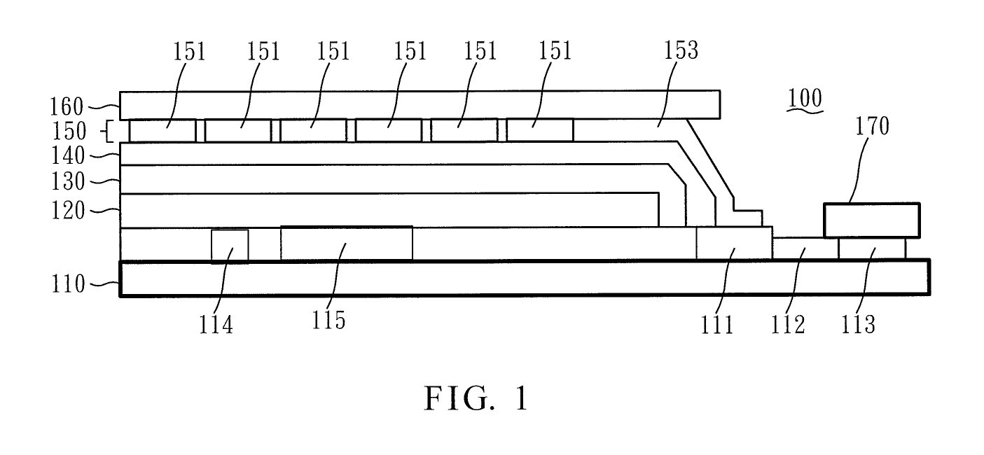

The present invention relates to an OLED touch display device. FIG. 1 is a first exemplary stack-up diagram of the OLED touch display device 100 in accordance with the present disclosure. As shown, the OLED touch display device 100 includes a thin film transistor (TFT) substrate 110, an OLED layer 120, a common voltage electrode layer 130, an encapsulation layer 140, at least one touch electrode layer 150, and a touch protective layer 160.

The TFT substrate 110 has a surface formed thereon a plurality of switch devices 111, a plurality of second touch traces 112, a plurality of conductive pads 113, a plurality of display thin film transistors 114, a plurality of display pixel electrodes 115, a plurality of gate lines (not shown), and a plurality of data lines (not shown). The material of the TFT substrate 110 can be selected from the group consisting of: polyethylene terephthalate (PET), polyimide (PI), polycarbonate (PC), cyclo-olefin polymers (COP), Poly methyl methacrylate (PPMA), triacetyl cellulose (TAC), and glass.

The common voltage electrode layer 130 includes at least one common voltage electrode. In this example, the common voltage electrode layer 130 is an anode common voltage electrode layer. In another example, the common voltage electrode layer 130 is a cathode common voltage electrode layer.

The OLED layer 120 is disposed between the TFT substrate 110 and the common voltage electrode layer 130. The encapsulation layer 140 is disposed at one side of the common voltage electrode layer 130 opposite to the OLED layer 120. The material of the encapsulation layer 140 can be the thermosetting resin or the UV-curing resin.

The at least one touch electrode layer 150 is disposed at one side of the common voltage electrode layer 130 opposite to the OLED layer 120, and includes a plurality of first touch traces 153 and a plurality of touch sense electrodes 151. The touch sense electrodes 151 are divided into a plurality of groups each having at least one touch sense electrode, and each group is corresponding to one of the conductive pads 113. The plurality of touch sense electrodes 151 are each a transparent conductive electrode.

The touch protective layer 160 is disposed at one side of the at least one touch electrode layer 150 opposite to the OLED layer 120, wherein the touch protective layer 160 is a substrate or a hardened coating layer.

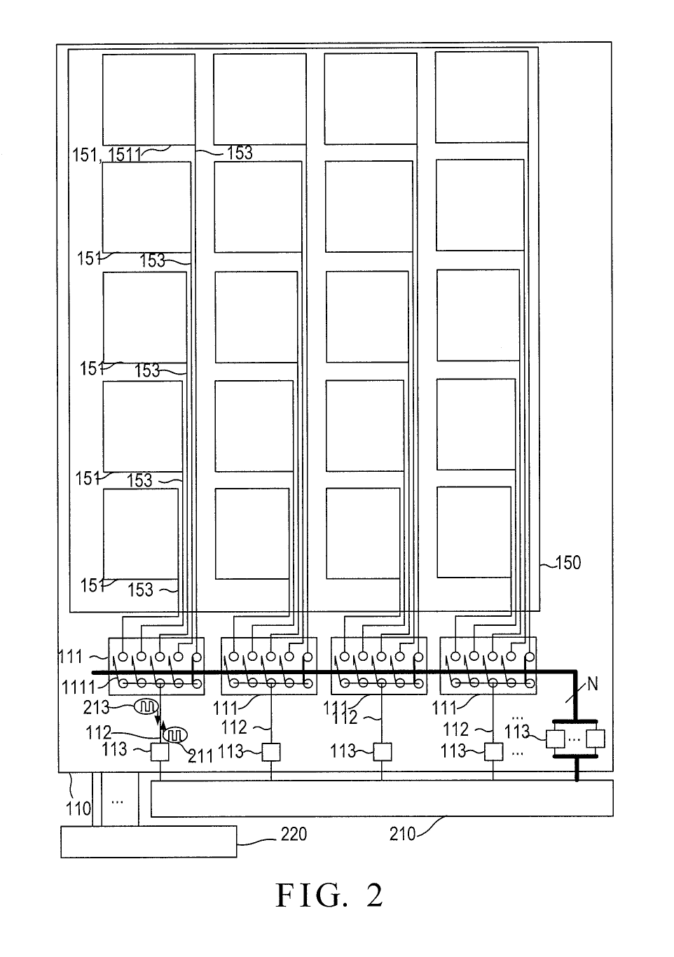

FIG. 2 is a schematic diagram of the OLED touch display device 100 in accordance with the present disclosure. As shown in FIG. 2, the OLED touch display device 100 further comprises a touch control circuit 210 and a display control circuit 220. As shown, each switch device 111 comprises a plurality of touch TFT switches 1111. There are M switch devices 111 and each switch device 111 comprises N touch TFT switches 1111, where M and N are each a positive integer. In this example, M is equal to 4 and N is equal to 5. It is noted that the values of M and N used herein are for illustrative purpose only, rather than for limitation of the claim scope.

The touch control circuit 210 may be soldered on an integrated circuit soft board (IC soft board) 170, which is electrically connected to the conductive pads 113. The touch control circuit 210 may be electrically connected to the conductive pads 113 through a soft cable.

The touch control circuit 210 is electrically connected to the N conductive pads 113 for controlling the plurality of touch TFT switches 1111 of the switch devices 111 to be turned on or off, so as to select a specific touch sense electrode 151 to be connected to the corresponding conductive pad 113. In this example, the touch control circuit 210 is electrically connected to M (=4) conductive pads 113 for transmitting touch stimulation signal and receiving touch sense signal, and N (=5) conductive pads 113 for controlling the switch devices 111.

In FIG. 2, the touch control circuit 210 outputs the control signal through the five conductive pads 113 to control the five touch TFT switches 1111 of each switch device 111 to be turned on or off. As shown, the rightmost touch TFT switch 1111 of each switch device 111 is turned on.

The plurality of touch sense electrodes 151 are corresponding to the plurality of first touch traces 153 one by one and each of the touch sense electrodes 113 is connected to the corresponding first touch trace 153, while any tow touch sense electrodes 151 are not connected with each other. Each of the first touch traces 153 is connected to one touch TFT switch 1111 of one switch device 111 corresponding thereto, and each of the switch devices 111 is connected to one second touch trace 112 and one conductive pad 113 corresponding thereto.

As shown, the touch sense electrode 1511 is connected to the corresponding touch TFT switch 1111 of the switch device 111 by the first touch trace 153. Due to the corresponding touch TFT switch 1111 being turned on, the touch sense electrode 1511 is electrically connected to the touch control circuit 210 through the second touch trace 112 and the conductive pad 113.

The touch control circuit 210 outputs a touch stimulation signal 211 to the selected touch sense electrode 1511 or receiving a touch sense signal 213 from the selected touch sense electrode 1511, so as to perform a touch detection operation.

The display control circuit 220 sequentially outputs a scan signal to one gate line, outputs a data signal to one data line, and outputs a zero voltage signal, a negative voltage signal or a positive voltage signal to the common voltage electrode layer 130 for performing a display operation.

In the prior art, it needs M×N (=20) traces to be routed between the touch sense electrodes and the touch control circuit. In contrast, from the aforementioned description, the present invention only needs M+N (=9) traces to connect the touch sense electrodes 151 and the touch control circuit 210. As the touch resolution is getting increased, it can dramatically reduce the number of traces, thereby greatly saving layout area and reducing the manufacturing cost.

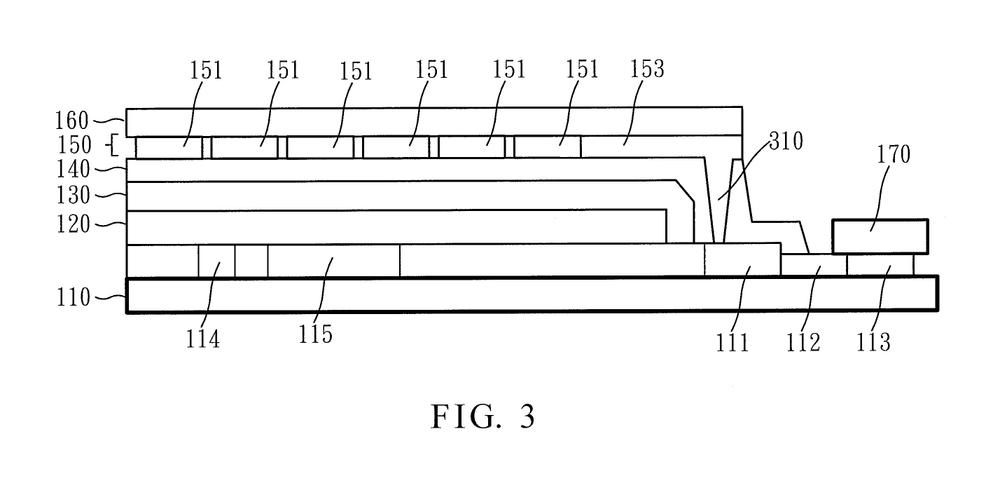

FIG. 3 is a second exemplary stack-up diagram of the OLED touch display device 100 in accordance with the present disclosure. The difference between FIG. 1 and FIG. 3 is that: in FIG. 1, the first touch traces 153 are connected to the touch TFT switches 1111 of the switch devices 111 along the edge of the encapsulation layer 140 and, in FIG. 3, the first touch traces 153 are connected to the touch TFT switches 1111 of the switch devices 111 by vias 310 in the encapsulation layer 140.

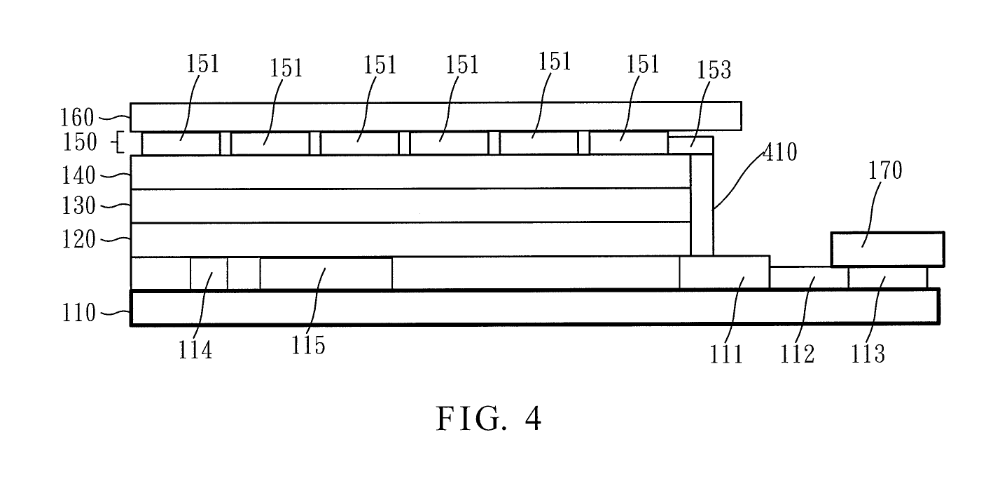

FIG. 4 is a third exemplary stack-up diagram of the OLED touch display device 100 in accordance with the present disclosure. The difference between FIG. 1 and FIG. 4 is that: in FIG. 1, the first touch traces 153 are connected to the touch TFT switches 1111 of the switch devices 111 along the edge of the encapsulation layer 140 and, in FIG. 4, the first touch traces 153 are connected to the touch TFT switches 1111 of the switch devices 111 by the conductive pillars 410 along the edge of the encapsulation layer 140. Each of the conductive pillars 410 is formed of conductive metal material which is selected from the group consisting of: chromium, barium, aluminum, silver, copper, titanium, nickel, tantalum, cobalt, tungsten, magnesium, calcium, potassium, lithium, indium, and an alloy thereof.

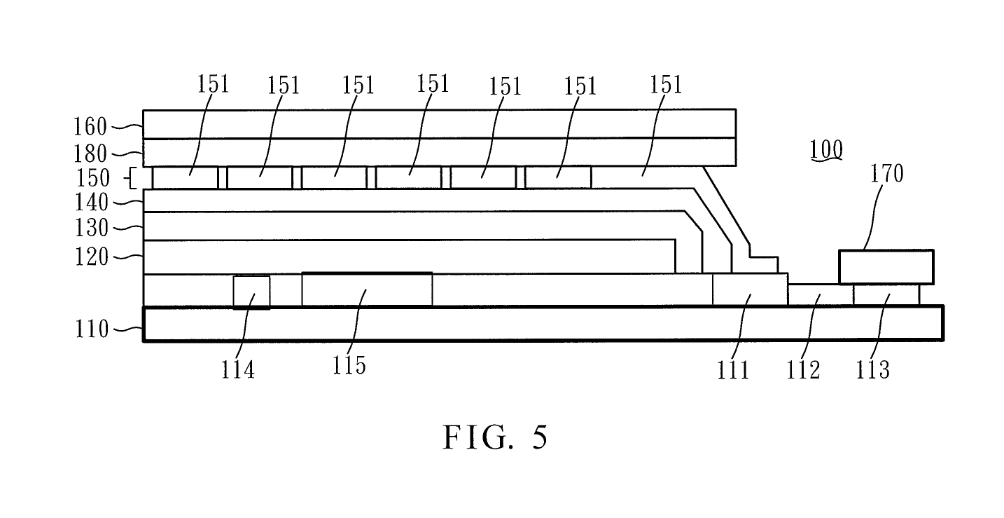

FIG. 5 is a fourth exemplary stack-up diagram of the OLED touch display device 100 in accordance with the present disclosure. FIG. 5 is similar to FIG. 1 except that there is a color filter layer 180 disposed between the at least one touch electrode layer 150 and the touch protective layer 160.

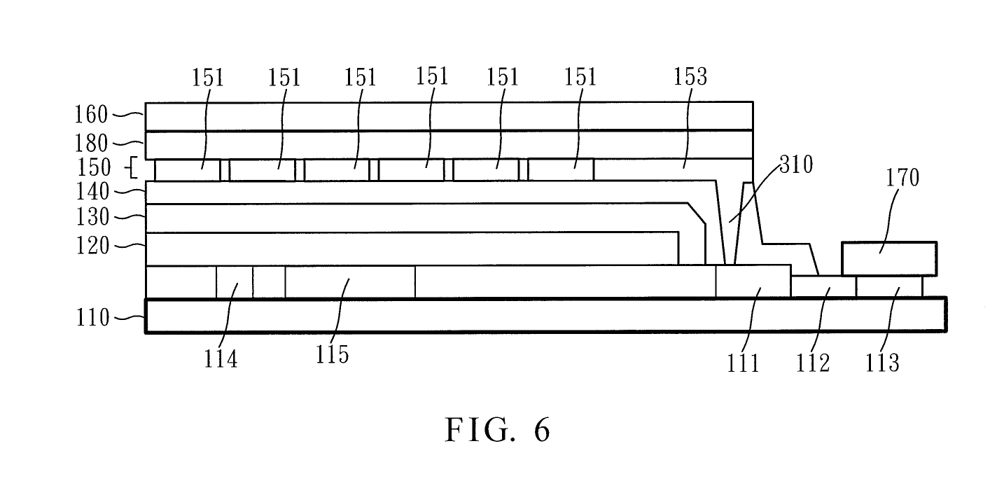

FIG. 6 is a fifth exemplary stack-up diagram of the OLED touch display device 100 in accordance with the present disclosure. FIG. 6 is similar to FIG. 3 except that there is a color filter layer 180 disposed between the at least one touch electrode layer 150 and the touch protective layer 160.

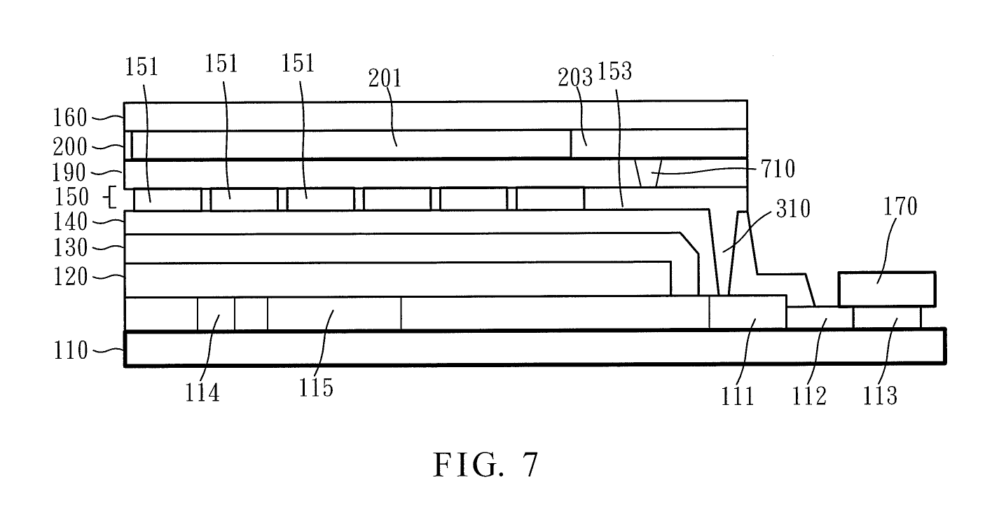

FIG. 7 is a sixth exemplary stack-up diagram of the OLED touch display device 100 in accordance with the present disclosure. FIG. 7 is similar to FIG. 3 except that, in FIG. 7, the OLED touch display device 100 further comprises an insulation layer 190 and a second touch electrode layer 200.

The second touch electrode layer 200 is disposed at one side of the touch protective layer 160 facing the OLED layer 120, and includes a plurality of third touch traces 203 and a plurality of touch sense electrodes 201. The touch sense electrodes 201 can be connected to the first touch traces 153 through the third touch traces 203 and the vias 710 in the insulation layer 190. Then, by using the first touch traces 153, the vias 310, the switch devices 111, the second touch traces 112 and the conductive pads 113, the touch sense electrodes 201 can be connected to touch control circuit 210. The OLED touch display device 100 in FIG. 7 has two touch layers to perform touch detection.

The insulation layer 190 is disposed at one side of the second touch electrode layer 200 facing the OLED layer 120.

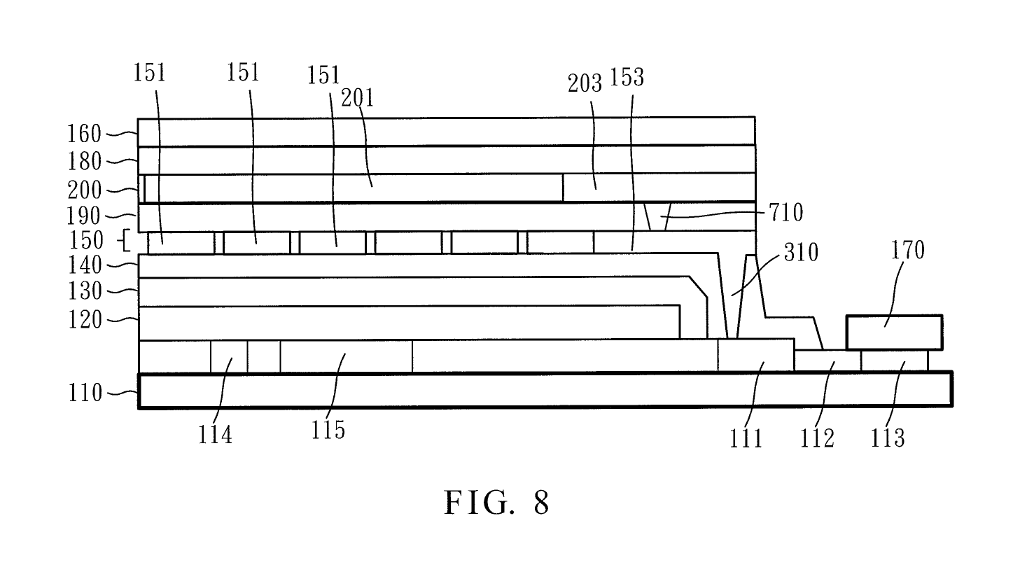

FIG. 8 is a seventh exemplary stack-up diagram of the OLED touch display device 100 in accordance with the present disclosure. FIG. 8 is similar to FIG. 7, except that, in FIG. 8, the OLED touch display device 100 further comprises a color filter layer 180 disposed between the second touch electrode layer 200 and the touch protective layer 160.

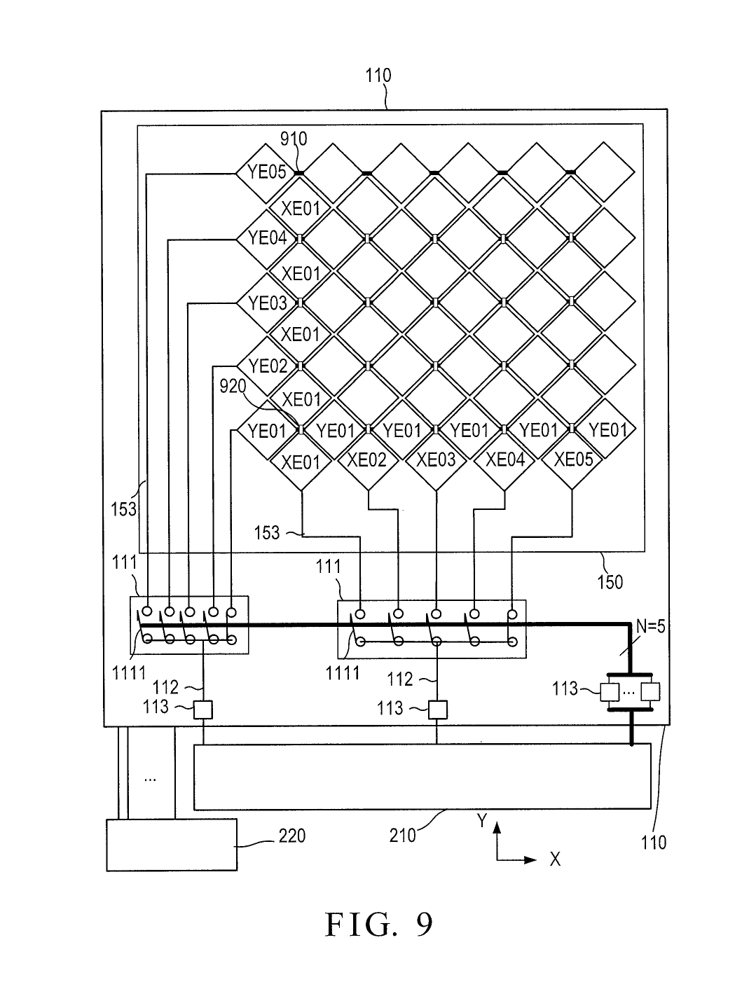

FIG. 9 is another schematic diagram of the OLED touch display device 100 in accordance with the present disclosure. As shown in FIG. 9, the at least one touch electrode layer 150 comprises a plurality of touch sense electrodes 151 divided into touch sense electrodes YE01, YE02, . . . , YE05 arranged along a first direction (X-axis direction) and touch sense electrodes XE01, XE02, . . . , XE05 arranged along a second direction (Y-axis direction). The touch sense electrode YE01 is connected to the adjacent touch sense electrode YE01 through a first touch bridge 910. A strip touch sense line along the first direction (X) is formed by the connected touch sense electrodes YE01. The touch sense electrode XE01 is connected to the adjacent touch sense electrode XE01 through a second touch bridge 920. A strip touch sense line along the second direction (Y) is formed by the connected touch sense electrodes XE01.

In the prior art, it needs 10 traces to be routed between the touch sense electrodes and the touch control circuit. In the instant application, it only needs M+N (=2+5=7) traces to connect the touch sense electrodes 151 and the touch control circuit 210. The OLED touch display device 100 may have only one touch electrode layer 150 to perform the self-capacitance touch detection or the mutual-capacitance touch detection by using the strip touch sense lines along the first direction (X-axis direction) and the second direction (Y-axis direction).

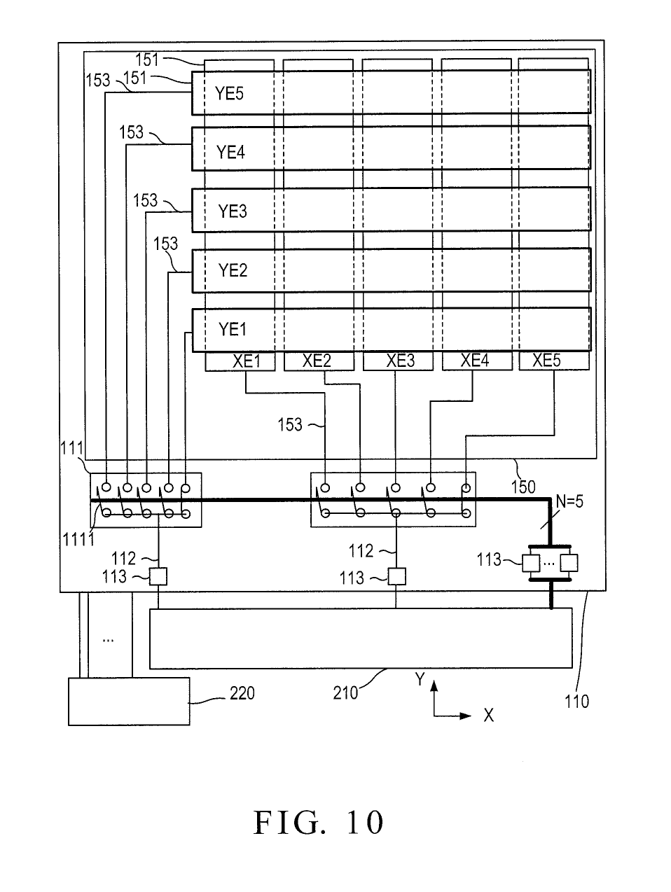

FIG. 10 is still another schematic diagram of the OLED touch display device 100 in accordance with the present disclosure. As shown in FIG. 10 with reference to FIG. 7 and FIG. 8, the at least one touch electrode layer 150 comprises a plurality of touch sense electrodes 151, each having a strip line shape, which are divided into first touch sense electrodes XE1, XE2, . . . , XE5 arranged along the first direction (X-axis direction) and second touch sense electrodes YE1, YE2, . . . , YE5 arranged along the second direction (Y-axis direction).

In the prior art, it needs 10 traces to be routed between the touch sense electrodes and the touch control circuit. In the instant application, it only needs M+N (=2+5=7) traces to connect the touch sense electrodes 151 and the touch control circuit 210. The OLED touch display device 100 may have the touch electrode layer 150 and the second touch electrode layer 200 to perform the self-capacitance touch detection or the mutual-capacitance touch detection by using the touch sense electrodes XE1, XE2, . . . , XE5 and YE1, YE2, YE5 along the first direction and the second direction.

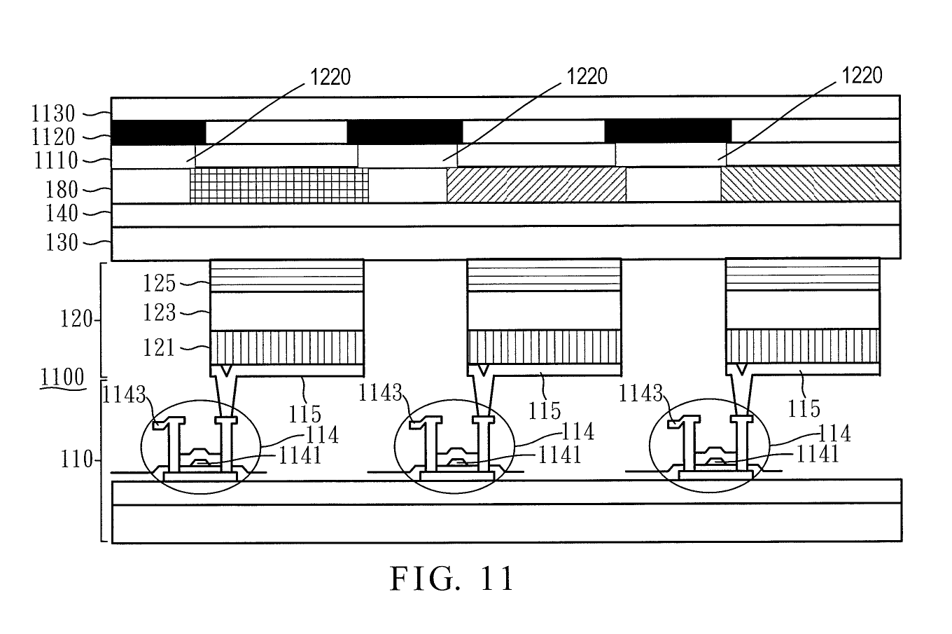

FIG. 11 is an eighth exemplary stack-up diagram of the OLED touch display device 1100 in accordance with the present disclosure. As shown, the OLED touch display device 1100 includes a thin film transistor (TFT) substrate 110, an OLED layer 120, a common voltage electrode layer 130, an encapsulation layer 140, a color filter layer 180, a metal mesh touch sense electrode layer 1110, a black matrix layer 1120, and an upper substrate 1130.

The TFT substrate 110 has a surface formed thereon a plurality of display thin film transistors 114, a plurality of display pixel electrodes 115, a plurality of gate lines 1141 and a plurality of data lines 1143, as well as a plurality of switch devices, a plurality of second touch traces and a plurality of conductive pads that are shown in FIG. 1 with numerals 111, 112 and 113. The material of the TFT substrate 110 may be selected from the group consisting of: polyethylene terephthalate (PET), polyimide (PI), polycarbonate (PC), cyclo-olefin polymers (COP), poly methyl methacrylate (PPMA), triacetyl cellulose (TAC), and glass.

The OLED layer 120 includes an electrical hole transporting layer 121, an emitting layer 123, and an electron transporting layer 125. The OLED layer 120 preferably emits white light, and the color filter layer 180 is used to filter out the whitelight thereby generating red, blue and green primary colors.

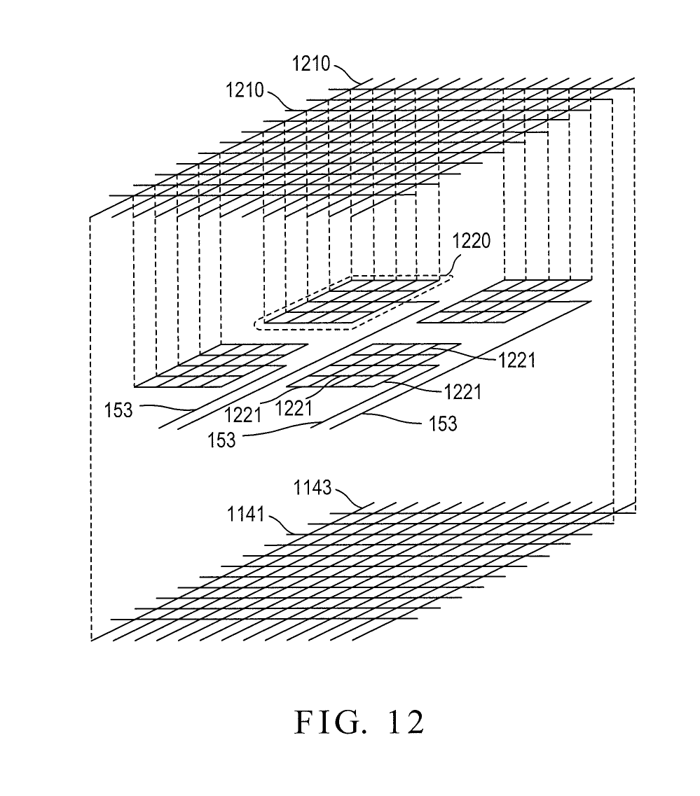

The black matrix layer 1120 is disposed at one side of the upper substrate 1130 that faces the OLED layer 120. FIG. 12 is a schematic view of the black matrix layer 1120 and the metal mesh touch sense electrode layer 1110 in accordance with the present disclosure. As shown, the black matrix layer 1120 comprises a plurality of opaque lines 1210 with insulating material that are black and opaque. The opaque lines 1210 of black insulating material are arranged as a checkerboard pattern. The locations of the opaque lines 1210 of black insulating material are corresponding to the locations of the gate lines 1141 and data lines 1143. Thus, a user cannot sense the existence of the gate lines 1141 and data lines 1143.

The metal mesh touch sense electrode layer 1110 is disposed at one side of the black matrix layer 1120 that faces the OLED layer 120. The metal mesh touch sense electrode layer 1110 comprises a plurality of touch sense electrodes, wherein each touch sense electrode is a metal mesh electrode 1220 formed by mesh lines 1221. The mesh lines 1221 of the metal mesh electrodes 1220 are disposed at locations corresponding to opaque lines 1210 of the black matrix layer 1120. The metal mesh electrodes 1220 may be connected to the touch control circuit 210 through the first touch traces 153.

The mesh line 1221 is formed of conductive metal material which is selected from the group consisting of chromium, barium, aluminum, silver, copper, titanium, nickel, tantalum, cobalt, tungsten, magnesium, calcium, potassium, lithium, indium, and an alloy thereof.

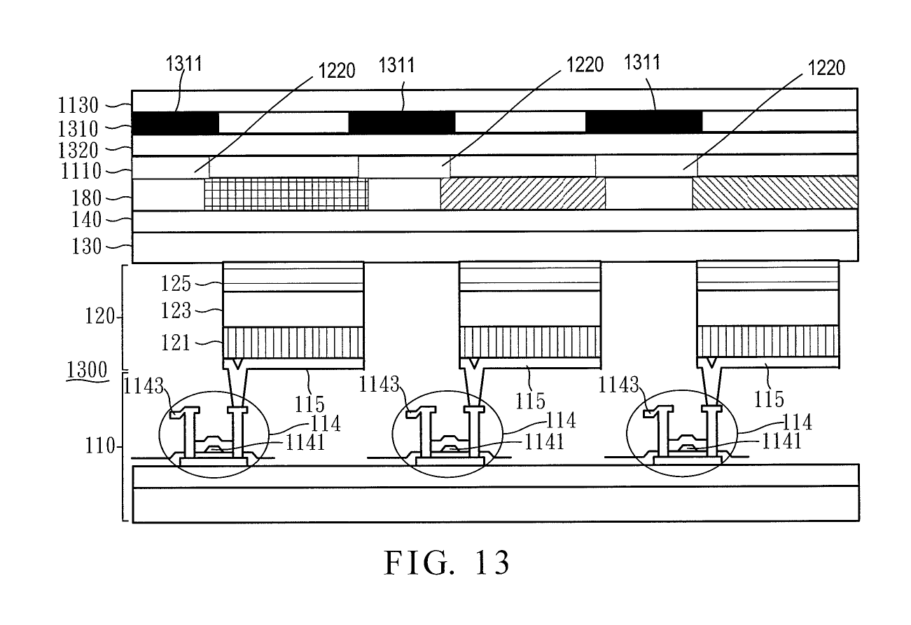

FIG. 13 is a ninth exemplary stack-up diagram of the OLED touch display device 1300 in accordance with the present disclosure. As shown, the OLED touch display device 1300 further comprises a black matrix layer 1310 and an insulation layer 1320. The black matrix layer 1310 is disposed at one side of the upper substrate 1130 that faces the OLED layer 120. The black matrix layer 1310 comprises a plurality of opaque lines with black conductive material. The locations of the opaque lines 1311 of black conductive material in black matrix layer 1310 are corresponding to the locations of the gate lines 1141 and data lines 1143. Corresponding to the metal mesh touch sense electrode layer 1110, the opaque lines 1311 of black conductive material may be formed to be a second touch sense electrode layer.

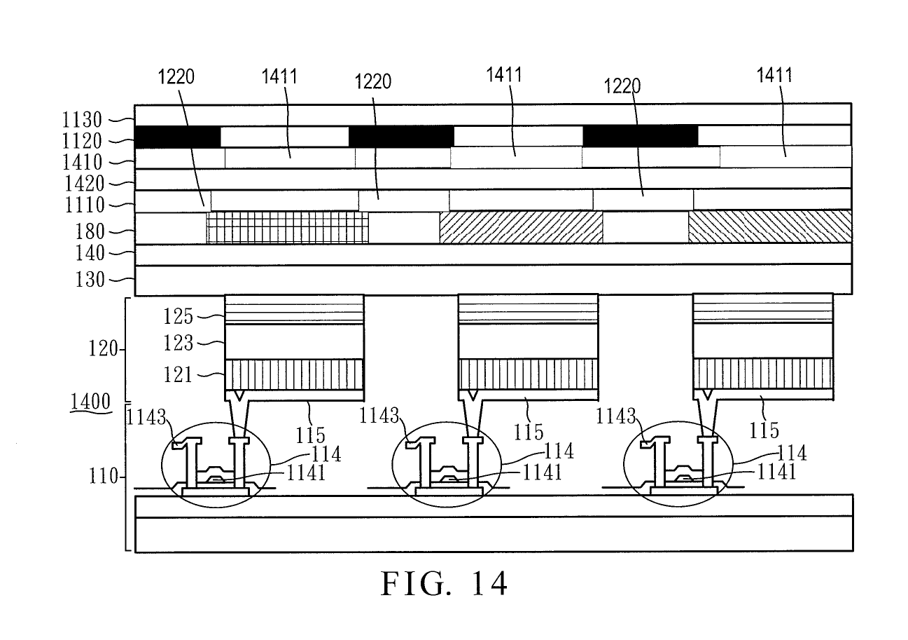

FIG. 14 is a tenth exemplary stack-up diagram of the OLED touch display device 1400 in accordance with the present disclosure. In comparison with FIG. 11, the OLED touch display device 1400 further comprises a second touch sense electrode layer 1410 and an insulation layer 1420. The second touch sense electrode layer 1410 is disposed at one side of the black matrix layer 1120 opposite to the OLED layer 120. The insulation layer 1420 is disposed at one side of the second touch sense electrode layer 1410 opposite to the OLED layer 120.

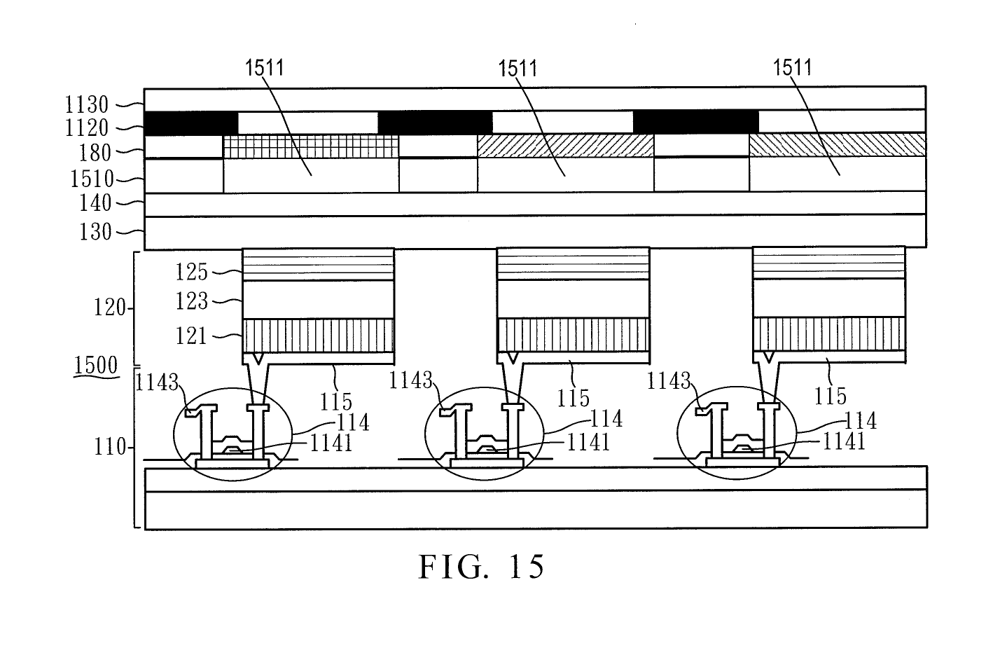

FIG. 15 is an eleventh stack-up diagram of the OLED touch display device 1500 in accordance with the present disclosure. In comparison with FIG. 11, the OLED touch display device 1500 comprises a transparent touch sense electrode layer 1510 disposed between the encapsulation layer 140 and the color filter layer 180. The transparent touch sense electrode layer 1510 comprises a plurality of touch sense electrodes 1511 and each of touch sense electrodes 1511 is a transparent conductive electrode.

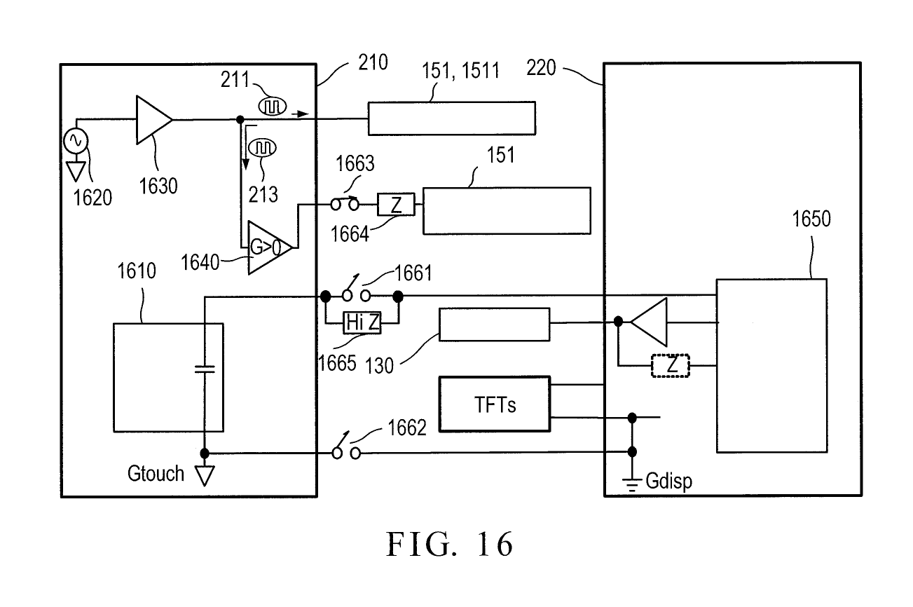

FIG. 16 is a schematic diagram illustrating the OLED touch display device 100 with the touch sense electrodes 151 being powered by a dedicated touch power source in accordance with the present disclosure. As shown in FIG. 16, the touch control circuit 210 includes a dedicated touch power source 1610, a touch stimulation signal generator 1620, a first amplifier 1630, and a second amplifier 1640. The display control circuit 220 comprises a dedicated display power source 1650.

The dedicated touch power source 1610 provides power to the touch stimulation signal generator 1620, the first amplifier 1630, and the second amplifier 1640 for performing touch detection. The touch stimulation signal generator 1620 generates the touch stimulation signal 211 amplified by the first amplifier and applied to a selected touch sense electrode 151. The touch control circuit 210 receives the touch sense signal 213 from the selected touch sense electrode 1511. The received the touch sense signal 213 is amplified by the second amplifier 1640 and applied to the other touch sense electrode 151. The voltage level of the other touch sense electrode 151 may be the same with the voltage level of the selected touch sense electrode 1511, such that the capacitance between the other touch sense electrode 151 and the selected touch sense electrode 1511 is zero, which can increase touch detection accuracy of the selected touch sense electrode 1511.

In another example, the second amplifier 1640 may be connected to a third switch 1663 and an impedance component 1664. The signal phase of the other touch sense electrode 151 may be the same with the signal phase of the selected touch sense electrode 1511, such that the capacitance between the other touch sense electrode 151 and the selected touch sense electrode 1511 may be reduced, which can also increase touch detection accuracy of the selected touch sense electrode 1511.

There are a first switch 1161 and a second switch 1162 disposed between the touch control circuit 210 and the display control circuit 220. Each of the first switch 1661 and the second switch 1662 is capable of switching its two terminals to be connected or disconnected. Alternatively, the first switch 1661 may include a high impedance element 1665 connected to the two terminals of the first switch 1661.

The dedicated display power source 1650 of the display control circuit 220 has a first grounding terminal denoted as a first ground (Gdisp). In one example of the present disclosure, the common voltage electrode layer 130, the display thin film transistors 114, the gate lines 1141, and the data lines 1143 are powered by the dedicated display power source 1650.

The display control circuit 220 is connected to the common electrode layer 130, the display thin film transistors 114, the gate lines 1141, and the data lines 1143, and so on for controlling a display unit to display an image.

In performing touch detection, the first switch 1661 and the second switch 1662 are off, and thus there is no current loop between the touch control circuit 210 and the display control circuit 220.

In view of the foregoing, it is known that, in prior art, a large number of traces are required to be routed between the touch sense electrodes and the touch control circuit and, in the instant application, only M+N (=9) traces are required to connect the touch sense electrodes 151 and the touch control circuit 210. As the touch resolution is getting increased, it can greatly reduce the number of traces, dramatically save layout area and decrease the manufacturing cost. Moreover, the pin number of the touch control circuit 210 can also be reduced. Thus, it can select a low pin count and low cost package to encapsulate the touch control circuit 210.

Although the present invention has been explained in relation to its preferred embodiment, it is to be understood that many other possible modifications and variations can be made without departing from the spirit and scope of the invention as hereinafter claimed.

What is claimed is:

1. An OLED touch display device, comprising:
a thin film transistor (TFT) substrate having a surface formed thereon a plurality of switch devices, a plurality of second touch traces, a plurality of conductive pads, a plurality of display TFTs, a plurality of display pixel electrodes, a plurality of gate lines, and a plurality of data lines, and each switch device comprising a plurality of touch TFT switches;
a common voltage electrode layer including at least one common voltage electrode;
an OLED layer disposed between the TFT substrate and the common voltage electrode layer;
an encapsulation layer disposed at one side of the common voltage electrode layer opposite to the OLED layer; and
at least one touch electrode layer disposed at one side of the common voltage electrode layer opposite to the OLED layer, and including a plurality of first touch traces and a plurality of touch sense electrodes divided into a plurality of groups each having at least one touch sense electrode, and each group corresponding to one of the conductive pads,
wherein the plurality of touch sense electrodes are corresponding to the plurality of first touch traces one by one and each of the touch sense electrodes is connected to the corresponding first touch trace, any tow touch sense electrodes are not connected with each other, each of the first touch traces is connected to one touch TFT switch of one switch device corresponding thereto, and each of the switch devices is connected to one second touch trace and one conductive pad corresponding thereto.

2. The OLED touch display device as claimed in claim 1, further comprising:
a touch control circuit electrically connected to the plurality of conductive pads for controlling the plurality of touch TFT switches of the switch devices to be turned on or off so as to select a specific touch sense electrode to be connected to the corresponding conductive pad, and outputting a touch stimulation signal to the selected touch sense electrode or receiving a touch sense signal from the selected touch sense electrode for performing a touch detection operation.

3. The OLED touch display device as claimed in claim 2, further comprising:
a display control circuit for sequentially outputting a scan signal to one gate line, outputting a data signal to one data line, and outputting a zero voltage signal, a negative signal or a positive voltage signal to the common voltage electrode layer for performing a display operation.

4. The OLED touch display device as claimed in claim 2, further comprising:
at least one first switch disposed between the touch control circuit and the common voltage electrode layer.

5. The OLED touch display device as claimed in claim 3, further comprising:
a second switch disposed between the touch control circuit and the display control circuit.

6. The OLED touch display device as claimed in claim 1, further comprising:
a touch protective layer disposed at one side of the at least one touch electrode layer, wherein touch protective layer is a substrate or a hardened coating layer.

7. The OLED touch display device as claimed in claim 1, wherein the plurality of touch sense electrodes are each a transparent conductive electrode.

8. The OLED touch display device as claimed in claim 1, wherein the plurality of touch sense electrodes are each a metal mesh electrode.

9. The OLED touch display device as claimed in claim 8, wherein the plurality of touch sense electrodes are each a black metal mesh electrode.

10. The OLED touch display device as claimed in claim 1, further comprising:
a color filter layer and a black matric layer.

11. The OLED touch display device as claimed in claim 10, wherein the plurality of touch sense electrodes are each a metal mesh electrode formed by mesh lines, and the mesh lines of the metal mesh electrodes are disposed at locations corresponding to opaque lines of the black matrix layer.
